(19) United States
(12) Patent Application Publication
(10) Pub. No.: US 2006/0019485 A1
(43) Pub. Date: Jan. 26, 2006

(54) Multi-layer wiring structure, semiconductor apparatus having multi-layer wiring structure, and methods of manufacturing them

(75) Inventors: Naoki Komai, Kanagawa (JP); Toshihiko Hayashi, Kanagawa (JP)

Correspondence Address: ROBERT J. DEPKE;LEWIS T. STEADMAN, TREXLER, BUSHNELL, GLANGLORGI, BLACKSTONE & MARR, 105 WEST ADAMS STREET, SUITE 3600, CHICAGO, IL, 60603-6299, US

(73) Assignee: Sony Corporation

(21) Appl. No.: 11/186,657

(22) Filed: Jul. 19, 2005

(30) Foreign Application Priority Data
Jul. 21, 2004 (JP) JP2004-213589

(51) Int. Cl. H01L 21/4763

(52) U.S. Cl. 438/627; 438/638; 438/639; 438/629

(57) ABSTRACT

A multi-layer wiring structure including an upper layer wiring (second buried wiring) connected to a buried wiring (first buried wiring) in lower layer wiring grooves (first wiring grooves) through connection conductors, wherein a protective film capable of enduring a cleaning treatment with hydrogen radicals or hydrogen plasma applied to the surface of the first buried wiring at the time of forming the connection conductors is formed on the inside surfaces of the wiring grooves to be filled with he second buried wiring and the wiring connection holes to be filled with the connection conductors which surfaces are liable to be eroded upon exposure to the atmosphere used in the cleaning treatment, whereby erosion of the insulation layers at the time of the cleaning is obviated, sufficient cleaning can be performed, and deterioration of characteristics can be improved.

### BACKGROUND OF THE INVENTION

The present invention relates to a multi-layer wiring structure, a semiconductor apparatus having a multi-layer wiring structure, and methods of manufacturing them.

For example, in semiconductor integrated circuit apparatuses, there is a need for more and more higher speed, smaller power consumption, smaller size and higher degree of integration, and, according to this, there is a need for more and more higher accuracy, higher degree of multiplicity of layers, lower wiring resistance, and larger reduction in mutual parasitic capacity of wirings.

To contrive a lower wiring resistance, Cu wiring with low resistance is adopted in place of Al used in ordinary wirings. Since Cu is poor in processability in pattern etching and the like, as in the case of Al, however, Cu wiring based on buried wiring is formed by forming wiring grooves in a layer insulation layer, and applying plating, sputtering or the like to bury Cu into the wiring grooves.

The reduction in the parasitic capacity between adjacent wirings in the wiring layer is conducted by a dual Damascene structure in which a layer insulation layer is provided with a hybrid insulation layer structure formed by lamination of a first insulation layer having an inorganic insulation layer and a low dielectric constant second insulation layer having an organic insulation layer, the above-mentioned Cu wiring is formed in the low dielectric constant second insulation layer, and the electrical connection between the Cu wiring and other wiring serving as an under layer is achieved by filling the wiring connection holes, i.e., so-called via holes, formed in the first insulation layer with a Cu connection conductor layer, simultaneously with the formation of the Cu wiring.

FIG. 14 is a general sectional view of a major part of a multi-layer wiring structure based on a hybrid dual Damascene structure. In FIG. 14, Cu is buried in first wiring grooves 102 formed in a first insulation layer 101, with a barrier metal layer 103 composed, for example, of a Ta film for inhibiting the diffusion of Cu into the insulation layer therebetween, to form a first buried wiring 104 based on the Cu wiring.

Then, a cap layer 105 having a function as a stopper of etching of the multi-layer wiring structure and a function as the above-mentioned barrier metal layer is formed thereon, and a second insulation layer 108 of the so-called hybrid structure composed of lamination of a lower insulation layer 106 having an inorganic insulation layer and an upper insulation layer 107 thereon having a low dielectric constant (so-called Low-k) organic insulation layer is formed thereon. Second wiring grooves 109 having a pattern according to the pattern of the upper insulation layer 107 are penetratingly formed in the upper insulation layer 107, while wiring connection holes 110 are penetratingly formed in the lower insulation layer 106.

A barrier metal layer 111 composed, for example, of a Ta film is formed on the inside wall surfaces of the second wiring grooves 109 and the wiring connection holes 110, then a Cu seed film (not shown), for example, as an under conductor layer for Cu plating is formed thereon, and Cu electroplating is thereafter conducted to simultaneously bury Cu into the second wiring grooves 109 and the wiring connection holes 110, thereby simultaneously forming a second buried wiring 112 and connection conductors 113.

In this manner, a multi-layer wiring structure is formed in which required portions of the second buried wiring 112 composed of the Cu wiring are electrically connected to the first buried wiring 104 similarly composed of the Cu wiring through the connection conductors 113 (in FIG. 14, only a pair of first and second wirings 104 and 112 are shown).

There have been proposed a multiplicity of methods of manufacturing a multi-layer wiring structure of the dual Damascene structure (see, for example, Japanese Patent Laid-open No. 2001-44189).

However, a problem as to reliability has been generated in all of the proposed methods.

In the configuration shown in FIG. 14, the formation of the second wiring grooves 109 and the wiring connection holes 110 is conducted as follows. As for example shown in FIG. 15A, the above-mentioned cap layer 105, the lower insulation layer 106 and the upper insulation layer 107 are formed on the first insulation layer 101 provided with the first buried wiring 104, then an etching mask layer 114 formed of SiO₂, for example, is formed on the upper insulation layer 107, thereafter etching by photolithography technology is applied thereto to form openings 114W in a pattern corresponding to the pattern of the second wiring groove 109 described referring to FIG. 14, a photoresist layer 115 is provided thereon by coating, and photolithograpy is conducted to form openings 115W in a pattern corresponding to the pattern of the wiring connection holes 110 descried referring to FIG. 13.

Then, first, the upper insulation layer 107 and the lower insulation layer 106 constituting the second insulation layer 108 and the cap layer 105 are etched through the openings 115W, to form the wiring connection holes 110 in the lower insulation layer 106. In this case, the cap layer 105 serves as a so-called etching stopper to determine the depth of etching.

Thereafter, as shown in FIG. 15B, the photoresist layer 115 shown in FIG. 15A is removed, and anisotropic etching by dry etching is applied to the upper insulation layer 107 through the openings 114W in the etching mask layer 114, to form the second wiring grooves 109.

Thereafter, a Cu burying operation is conducted. In this Cu burying operation, the barrier metal layer 111 shown in FIG. 14 and the Cu seed film (not shown) to be the under conductor layer for Cu plating are formed on the inner peripheral surfaces of the wiring connection holes 110 and the first wiring grooves 109, thereafter electroplating is conducted to once form a thick Cu plating layer (not shown) which is thick enough to sufficiently fill up the wiring connection holes 110 and the second wiring grooves 109, and the plating layer is polished by CMP (Chemical Mechanical Polishing) from the surface thereof, to remove the Cu layer formed on the second insulation film 107 in areas other than the areas of the second wiring grooves 103, thereby limitatively bury Cu in the wiring connection holes 110 and the wiring grooves 109, as shown in FIG. 14.

Incidentally, prior to the Cu burying operation applied to the wiring connection holes 110 and the wiring grooves 109 as above-mentioned, a cleaning treatment is applied to the bottom surfaces of the wiring connection holes 110, i.e., the surface of the first buried wiring 104 to ensure that Cu used in the Cu burying operation can make good mechanical and electrical contact with the first buried wiring 104.

The acceptability of the cleaning, for example, the acceptability of removal of the residue upon the above-mentioned dry etching affects greatly the electrical and mechanical properties, or reliability, of the multi-layer wiring structure.

Examples of the cleaning method include a first method of cleaning by use of an aqueous solution of hydrofluoric acid or an organic acid, a second method of cleaning by physical sputter cleaning, or so-called reverse sputter, using argon ions, a third method of cleaning by reduction of oxides by high-temperature hydrogen, and combinations of these method.

However, in the cleaning by hydrofluoric acid according to the first method, the removal of the damaged layer generated upon the dry etching leads to the generation of variations in wiring width, i.e., deviations from the designed width, or the so-called CD (Change Dimension). On the other hand, the cleaning by use of an aqueous solution of organic acid has a problem as to the performance of removal of the etching residue.

The second method based on the reverse sputter is a method by physical beating, so to speak. Therefore, as shown in FIG. 16, the same CD as above-mentioned is generated in which the wiring grooves 108 become wider toward the opening side.

When the wiring grooves 108 thus become wider, the adjacent wirings become closer to each other, possibly enhancing the parasitic capacity or causing short circuits, with the result of a lowering in reliability.

In the reduction by hydrogen according to the third method, the reduction of Cu would be insufficient if the resist residue is present.

In contrast, cleaning by use of hydrogen radicals promises favorable reduction of Cu. However, in the case of the above-mentioned hybrid structure, there results erosion of the upper insulation layer 107 composed of the organic insulation layer, for example, PAE (polyaryl ether), so that the second wiring grooves 109 would be broadened as schematically shown in FIG. 17, and the adjacent wirings would become closer to each other in the same manner as above-mentioned, leading to a lowered reliability such as enhanced parasitic capacity and generation of short circuits.

Besides, in the case of a laminate wiring structure of the dual Damascene structure other than the hybrid structure in which the organic insulation layer of PAE, for example, is used, for example, in the case where alkyl-containing SiO₂ such as SiCOH is used as the second insulation layer, the alkyl groups would be drawn out during the cleaning by the hydrogen radicals, leading to deterioration of the electrical and mechanical characteristics of the insulation layer.

### SUMMARY OF THE INVENTION

In relation to multi-layer wiring structures and semiconductor apparatuses having the multi-layer wiring structure, there is a need for a multi-layer wiring structure, a semiconductor apparatus having a multi-layer wiring structure, and methods for manufacturing them in which it is possible to securely obviate the problem of deterioration of characteristics attendant on the cleaning treatment mentioned above.

According to an embodiment of the present invention, there is provided a multi-layer wiring structure comprising at least: a first insulation layer having a first buried wiring formed in a first wiring groove; and a second insulation layer formed on the first insulation layer and having a second buried wiring formed in a second wiring groove; wherein at least the second insulation layer is provided, under the second wiring groove formed in the second insulation layer, with a wiring connection hole filled with a connection conductor for connection between the second buried wiring in the second wiring groove and the first buried wiring in the first insulation layer; a protective film capable of enduring a cleaning treatment by a hydrogen plasma treatment or a hydrogen radical treatment carried out prior to the formation of the connection conductor in the wiring connection hole is formed to cover the inside surfaces of the second wiring groove and the wiring connection hole in the second insulation layer; and the protective film includes a barrier metal layer for the insulation film or the connection conductor and the second buried wiring.

According to another embodiment of the present invention, there is provided a multi-layer wiring structure comprising at least: a first insulation layer having a first buried wiring formed in a first wiring groove; and a second insulation layer formed on the first wiring layer and having a second buried wiring formed in a second wiring groove; wherein at least the second insulation layer has a laminate structure of a lower insulation layer having an inorganic insulation layer and an upper insulation layer having a low dielectric constant organic insulation layer; the upper insulation layer in the second insulation layer is provided with the second wiring groove filled with the second buried wiring, and is provided under the second wiring groove with a wiring connection hole filled with a connection conductor for connection between the second buried wiring in the second wiring groove and the first buried wiring in the lower insulation layer; a protective film capable of enduring a cleaning treatment by a hydrogen plasma treatment or a hydrogen radical treatment carried out prior to the formation of the connection conductor in the wiring connection hole is formed to cover at least the inside surface of the second wiring groove in the upper insulation layer having the organic insulation layer; and the protective layer has a barrier metal layer for an insulation film or the connection conductor and the second buried wiring.

According to a further embodiment of the present invention, there is provided a semiconductor apparatus having a multi-layer wiring structure on a semiconductor substrate having at least a semiconductor layer provided with a semiconductor device, wherein the multi-layer wiring structure includes at least a first insulation layer having a first buried wiring formed in a first wiring groove, and a second insulation layer formed on the first insulation layer and having a second buried wiring formed in the second wiring groove; at least the second insulation layer is provided, under the second wiring groove formed in the second insulation layer, with a wiring connection hole filled with a connection conductor for connection between the second buried wiring in the second wiring groove and the first buried wiring in the first insulation layer; a protective film capable of enduring a cleaning treatment by a hydrogen plasma treatment or a hydrogen radical treatment carried out prior to the formation of the connection conductor in the wiring connection hole is formed to cover the inside surfaces of the second wiring groove and the wiring connection hole in the second insulation layer; and the protective film has an insulation film or a barrier metal layer for the connection conductor and the second buried wiring.

According to yet another embodiment of the present invention, there is provided a semiconductor apparatus having a multi-layer wiring structure on a semiconductor substrate having at least a semiconductor layer provided with a semiconductor device, wherein the multi-layer wiring structure includes at least a first insulation layer having a first buried wiring formed in a first wiring groove, and a second insulation layer formed on the first insulation layer and having a second buried wiring formed in a second wiring groove; at least the second insulation layer has a laminate structure of an under insulation layer having an inorganic insulation layer and an upper insulation layer having a low dielectric constant organic insulation layer; the upper insulation layer in the second insulation layer is provided with the second wiring groove filled with the second buried wiring, and is provided under the second wiring groove with a wiring connection hole filled with a connection conductor for connection between the second buried wiring in the second wiring groove and the first buried wiring in the lower insulation layer; a protective film capable of enduring a cleaning treatment by a hydrogen plasma treatment or a hydrogen radical treatment carried out prior to the formation of the connection conductor in the wiring connection hole is formed to cover at least the inside surface of the second wiring groove in the upper insulation layer having the organic insulation layer; and the protective layer has an insulation film or a barrier metal layer for the connection conductor and the second buried wiring.

According to a yet further embodiment of the present invention, there is provided a method of manufacturing a multi-layer wiring structure, including the steps of: forming a second insulation layer on a first insulation layer having a first buried wiring formed in a first wiring groove; forming a wiring connection hole in the second insulation layer, on the upper side of a predetermined portion of the first buried wiring; forming a second wiring groove communicated with the wiring connection hole; forming a protective film on the inside surfaces of the wiring connection hole and the second wiring groove in the second insulation layer; thereafter cleaning an upper surface of the first wiring at the bottom surface of the wiring connection hole by a hydrogen plasma treatment or a hydrogen radical treatment; and thereafter forming a connection conductor connected to the first buried wiring and a second buried wiring in the wiring connection hole and in the second wiring groove, respectively; wherein the protective film has an insulation film or a barrier metal layer for the connection conductor and the second buried wiring, the insulation film or barrier metal layer being capable of enduring the hydrogen plasma treatment or the hydrogen radical treatment.

According to still another embodiment of the present invention, there is provided a method of manufacturing a multi-layer wiring structure, including the steps of: forming a second insulation layer by sequentially forming a lower insulation layer having an inorganic insulation layer and an upper insulation layer having a low dielectric constant organic insulation layer, on a first insulation layer having a first buried wiring formed in a first wiring groove; forming a wiring connection hole in at least the lower insulation layer of the second insulation layer, on the upper side of a predetermined portion of the first buried wiring; forming a second wiring groove communicated with the wiring connection hole limitatively in the upper insulation layer of the second insulation layer; forming a protective film on the inside surface of the upper insulation layer fronting on the second wiring groove of the second insulation layer, at least; thereafter cleaning an upper surface of the first wiring at the bottom surface of the wiring connection hole by a hydrogen plasma treatment or a hydrogen radical treatment; and thereafter forming a connection conductor connected to the first buried wiring and a second buried wiring in the wiring connection hole and in the second wiring groove, respectively; wherein the protective film has an insulation film or a barrier metal layer for the connection conductor and the second buried wiring, the insulation film or barrier metal layer being capable of enduring the hydrogen plasma treatment or the hydrogen radical treatment.

In each of the above-mentioned methods of manufacturing a multi-layer wiring structure according to the present invention, the step of forming the protective film having the insulation film may have the steps of forming the insulation film on the inside surfaces of the wiring connection hole and the second wiring groove, and removing the insulation film on the bottom surface of the wiring connection hole intersecting the depth direction of the wiring connection hole and the second wiring groove by anisotropic etching including reactive ion etching to thereby expose the first buried wiring.

In each of the above-mentioned methods of manufacturing a multi-layer wiring structure according to the present invention, the step of forming the protective film having the barrier metal layer may have the step of applying sputtering and reverse sputtering to the inside surfaces of the wiring connection hole and the second wiring groove to remove the barrier metal layer on the bottom surface of the wiring connection hole intersecting the depth direction of the wiring connection hole and the second wiring groove, thereby exposing the first buried wiring.

According to a still further embodiment of the present invention, there is provided a method of manufacturing a semiconductor apparatus having a multi-layer wiring structure on a semiconductor substrate having at least a semiconductor layer provided with a semiconductor device, wherein the multi-layer wiring structure is manufactured by a method including the steps of: forming a second insulation layer on a first insulation layer having a first buried wiring formed in a first wiring groove; forming a wiring connection hole in the second insulation layer, on the upper side of a predetermined portion of the first buried wiring; forming a second wiring groove communicated with the wiring connection hole; forming a protective film on the inside surfaces of the wiring connection hole and the second wiring groove in the second insulation layer; thereafter cleaning an upper surface of the first wiring at the bottom surface of the wiring connection hole by a hydrogen plasma treatment or a hydrogen radical treatment; and thereafter forming a connection conductor connected to the first buried wiring and a second buried wiring in the wiring connection hole and in the second wiring groove, respectively; the protective film having an insulation film or a barrier metal layer for the connection conductor and the second buried wiring, the insulation film or barrier metal layer being capable of enduring the hydrogen plasma treatment or the hydrogen radical treatment.

According to more another embodiment of the present invention, there is provided a method of manufacturing a semiconductor apparatus having a multi-layer wiring structure on a semiconductor substrate having at least a semiconductor layer provided with a semiconductor device, wherein the multi-layer wiring structure is manufactured by a method including the steps of: forming a second insulation layer by sequentially forming a lower insulation layer having an inorganic insulation layer and an upper insulation layer having a low dielectric constant organic insulation layer, on a first insulation layer having a first buried wiring formed in a first wiring groove; forming a wiring connection hole in at least the lower insulation layer of the second insulation layer, on the upper side of a predetermined portion of the first buried wiring; forming a second wiring groove communicated with the wiring connection hole limitatively in the upper insulation layer of the second insulation layer; forming a protective film on the inside surface of the upper insulation layer fronting on the second wiring groove of the second insulation layer, at least; thereafter cleaning an upper surface of the first wiring at the bottom surface of the wiring connection hole by a hydrogen plasma treatment or a hydrogen radical treatment; and thereafter forming a connection conductor connected to the first buried wiring and a second buried wiring in the wiring connection hole and in the second wiring groove, respectively; the protective film having an insulation film or a barrier metal layer for the connection conductor and the second buried wiring, the insulation film or barrier metal layer being capable of enduring the hydrogen plasma treatment or the hydrogen radical treatment.

Incidentally, in the present invention, the names of the first and second insulation layers, the first and second wiring grooves, and the first and second buried wirings are so used that, in a multi-layer wiring structure, the lower one of a pair of layers adjacent to each other in the lamination direction in each layer is referred to as the first one, and the other one of the pair of layers is referred to as the second one; in a three or more layer wiring, the lower one of a pair of wiring layers adjacent to each other in the lamination direction is referred to as the first wiring, and the other one of the pair of wiring layers is referred to as the second wiring.

As has been described above, in the multi-layer wiring structure according to the present invention, even in the case where the second insulation layer is composed of alkyl-containing SiO₂ such as SiCOH, the presence of the protective film obviates the inconvenience of erosion of the second insulation layer during the cleaning treatment by hydrogen radicals or hydrogen plasma for cleaning the surface of the first buried wiring fronting on the bottom surface of the wiring connection hole prior to the filling of the wiring connection hole with the connection conductor.

Therefore, the connection conductor can be formed on the sufficiently cleaned first buried wiring through the wiring connection hole, so that a lower resistance contact can be contrived.

In addition, since the erosion of the inside surface of the second insulation layer is obviated, the generation of the above-mentioned CD, or variations in the wiring width, can be obviated, so that it is possible to configure a multi-layer wiring structure which has a stable, highly reliable high-density buried wiring desired and which is excellent in high-speed operation property.

In addition, in the multi-layer wiring structure according to the present invention, at least the second insulation layer has a hybrid structure in which the upper insulation layer provided with the buried wiring has an organic insulation layer lower in dielectric constant than the lower insulation layer provided with the wiring connection hole filled with the connection conductor, and, even in the case of using the organic insulation layer composed of the above-mentioned PAE, for example, the presence of the protective film on the organic insulation layer fronting on the inside of the wiring groove ensures that the erosion of the inside surface is similarly obviated. Therefore, the generation of the above-mentioned CD, or variations in wiring width, can be obviated, and it is possible to configure a multi-layer wiring structure which has a stable, highly reliable high-density buried wiring desired and which is excellent in high speed operation property.

According to the semiconductor apparatus of the present invention, the multi-layer wiring structure portion thereof has the above-mentioned multi-layer wiring structure according to the present invention, and, therefore, it is possible to configure a semiconductor apparatus which is excellent in high speed operation property and high in reliability.

According to the method of manufacturing a multi-layer wiring structure and the method of manufacturing a semiconductor apparatus having a multi-layer wiring structure of the present invention, the presence of the protective film ensures that the surface of the first buried wiring to be brought into contact with the connection conductor can be sufficiently cleaned by hydrogen radicals or hydrogen plasma prior to the formation of the connection conductor. Therefore, it is possible to configure a multi-layer wiring structure and a semiconductor apparatus having a multi-layer wiring structure, with excellent characteristics and in high yield.

### BRIEF DESCRIPTION OF THE DRAWINGS

FIG. 1 is a general sectional view of an example of a multi-layer wiring structure according to the present invention and a semiconductor apparatus having the multi-layer wiring structure.

FIG. 2 is a sectional view of a major part of FIG. 1.

FIG. 3 is a general sectional view of a major part in one step in one embodiment of the manufacturing method according to the present invention.

FIG. 4 is a general sectional view of a major part in one step in the one embodiment of the manufacturing method according to the present invention.

FIG. 5 is a general sectional view of a major part in one step in the one embodiment of the manufacturing method according to the present invention.

FIG. 6 is a general sectional view of a major part in one step in the one embodiment of the manufacturing method according to the present invention.

FIG. 7 is a general sectional view of a major part in one step in the one embodiment of the manufacturing method according to the present invention.

FIG. 8 is a general sectional view of a major part in one step in the one embodiment of the manufacturing method according to the present invention.

FIG. 9 is a general sectional view of a major part in one step in the one embodiment of the manufacturing method according to the present invention.

FIG. 10 is a general sectional view of a major part in one step in the one embodiment of the manufacturing method according to the present invention.

FIG. 11 is a general sectional view of a major part in one step in the one embodiment of the manufacturing method according to the present invention.

FIG. 12 is a general sectional view of a major part in one step in another embodiment of the manufacturing method according to the present invention.

FIG. 13 is a general sectional view of a major part in one step in another embodiment of the manufacturing method according to the present invention.

FIG. 14 is a sectional view showing a part of a multi-layer wiring structure according to a related art.

FIGS. 15A and 15B are each a sectional view, in a manufacturing step, of a part of one example of the multi-layer wiring structure according to the related art.

FIG. 16 is a sectional view, after cleaning, of a wiring connection hole in a method of manufacturing a multi-layer wiring structure according to a related art.

FIG. 17 is a sectional view, after cleaning, of a wiring connection hole in a method of manufacturing a multi-layer wiring structure according to a related art.

### DETAILED DESCRIPTION OF THE PREFERRED EMBODIMENTS

Embodiments of the present invention will be described referring to the drawings. It should be noted, however, that the present invention is not limited to the embodiments.

### Embodiment of Multi-layer Wiring Structure and Semiconductor Apparatus Having the Multi-Layer Wiring Structure

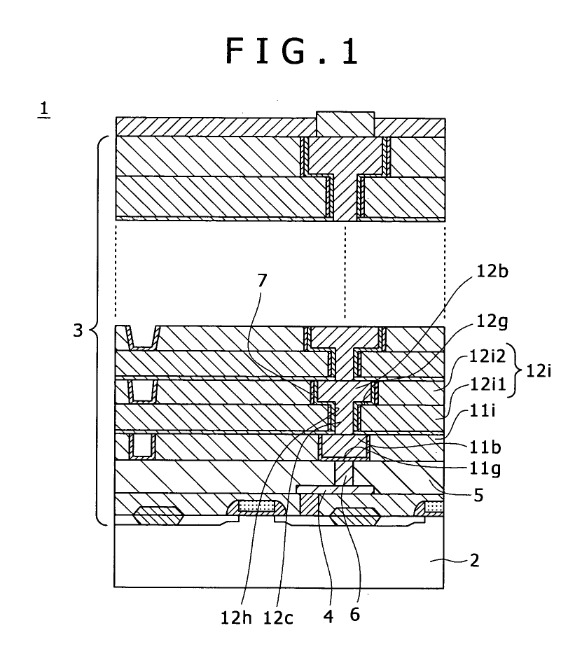

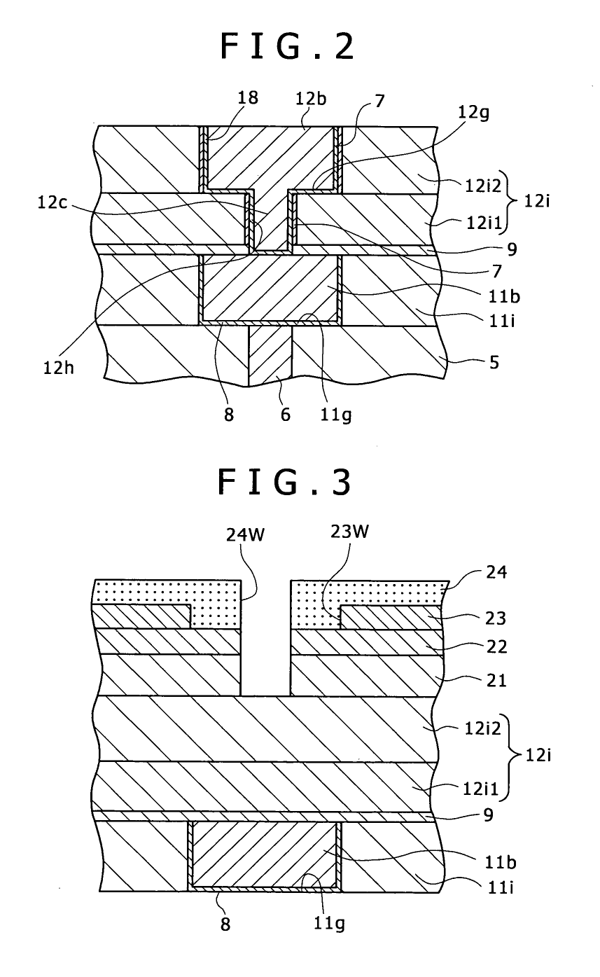

FIG. 1 is a general sectional view of a major part of one embodiment of the semiconductor apparatus 1 having a multi-layer wiring structure of a hybrid dual Damascene structure according to the present invention, and FIG. 2 is a sectional view schematically showing a major part of the multi-layer wiring structure 1.

The multi-layer wiring structure 1 is based on the Damascene structure, and, in this embodiment, in FIG. 1, a first buried wiring 11b is a wiring of a single Damascene structure serving as a lowermost layer, a second buried wiring 12b is provided thereon, and the whole wiring including the second wiring 12b and the upper layers has a hybrid dual Damascene structure.

The semiconductor apparatus 1 according to the present invention has a configuration in which a multi-layer wiring structure 3 according to the present invention is provided on a semiconductor substrate 2 having at least a semiconductor layer provided at least with an array of semiconductor devices, for example, insulated gate type field effect transistor MOSes.

In the example of FIG. 1, a wiring 4 composed of an ordinary metallic layer having a required pattern connected to the semiconductor devices is formed on the semiconductor substrate 2, and is buried by a flattening insulation layer 5 of boron phosphosilicate glass, for example. Predetermined portions of the wiring 4 are electrically connected to the first buried wiring 11b serving as the lower layer (which will be described later) of the multi-layer wiring structure 3, by a connection conductors 6 composed of tungsten plugs, for example.

The multi-layer wiring structure 3 has a configuration in which first wiring grooves 11g having a pattern according to a wiring pattern are cut in a first insulation layer 11i composed of an inorganic insulation layer of, for example, SiOC serving as a lower layer, and the first buried wiring 11b of a highly electrically conductive material, for example, Cu is formed in the first wiring grooves 11g.

A second insulation layer 12i on the upper side of the first insulation layer 11i has a laminate structure of a lower insulation layer 12i1 of a comparatively higher dielectric constant material, for example, SiOC and an upper insulation layer 12i2 composed of an insulation layer of a low dielectric constant organic material, for example, PAE (polyaryl ether); in this case, second wiring grooves 12g in a pattern corresponding to the wiring pattern are dug in the upper insulation layer 12i2 over the entire thickness of the upper insulation layer 12i2, and a second buried wiring 12b of Cu, for example, is similarly formed in the second wiring grooves 12g.

The lower insulation layer 12i1 of the second insulation layer 12i is provided with wiring connection holes 12h between connection portions of the first buried wiring 11b and the second buried wiring 11b, and the wiring connection holes 12h are similarly filled with connection conductors 12c of Cu.

The connection conductors 6 composed, for example, of the W plugs and the second buried wiring 12b can be integrally formed by simultaneously burying Cu, for example.

Then, in the present invention, a protective film 7 is depositedly formed to cover the inside surface of the organic insulation layer constituting the upper insulation layer 12i2 of the second insulation layer 12i of the hybrid structure, at least. As shown in FIG. 2, the protective film 7 can be formed over the inside surfaces of the wiring connection holes 11c and the wiring grooves 12b, for example.

The protective film 7 can be constituted, for example, of SiO₂, SiN, SiC, or SiCOH in a thickness of 2 to 3 nm capable of enduring hydrogen radicals or hydrogen plasma in a cleaning treatment of the buried wiring 11b in the lower layer fronting on the bottom surfaces of the wiring connection holes 12h, prior to the formation of the connection conductors 6 into the wiring connection holes 12h.

Now, an embodiment of the method of manufacturing the multi-layer wiring structure according to the present invention mentioned above will be described below, referring to FIGS. 3 to 10. The figures each show a sectional view of a major part of the desired multi-layer wiring structure 3, in each step of the manufacturing process.

### First Embodiment of the Method of Manufacturing the Multi-layer Wiring Structure

First, as shown in FIG. 3, the first insulation layer 11i of SiOC, for example, is formed on the flattening insulation layer 5 (not shown) on the semiconductor substrate 2 (not shown) by a PE-CVD (Plasma Enhanced-Chemical Vapor Deposition) process. The above-mentioned first wiring grooves 11g are formed in the first insulation layer 11i by RIE (Reactive Ion Etching) or the like.

The inside surfaces of the first wiring grooves 11g are coated with a barrier metal layer 8 of SiN, SiC or the like by, for example, sputtering, and the first buried wiring 11b composed of a low-resistance metal, for example, Cu, is formed on the inside surfaces, with the barrier metal layer 8 therebetween. The formation of the buried wiring 11b is conducted by a method in which a layer of Cu, for example, is formed in a thickness sufficiently greater than the depth of the wiring grooves 11g by sputtering, plating or the like, and then the layer is polished from the surface thereof by CMP (Chemical Mechanical Polishing) so that the surface of the buried wiring 11b in the wiring grooves 11g and the surface of the insulation layer 11i are flattened to be flush with each other.

A barrier metal layer for restraining the diffusion of the second buried wiring 12b and a cap layer 9 to be a stopper for etching or the like (described later) are formed on the whole area of the flattened surface by depositing, for example, SiN, SiC by PE-CVD or the like.

Subsequently, the second insulation layer 12i is formed on the whole area of the cap layer 9. The second insulation layer 12i is formed, for example, by depositing SiOC by PE-CVD or the like to form the lower insulation layer 12i1, and subsequently forming thereon the upper insulation layer 12i2 composed of a low dielectric constant organic insulation layer of PAE, for example.

The upper and lower insulation layers 12i2 and 12i1 are provided with the above-mentioned second wiring grooves 12g and the wiring connection holes 12h communicated therewith.

The second wiring grooves 12g and the wiring connection holes 12h may be formed, for example, by the known triple hard mask method, whereby they can be formed with high accuracy.

In this case, as shown in FIG. 3, an insulation layer 21 to be the mask layer for etching (described later) which is formed, for example, of SiO₂, an intermediate mask layer 22 of, for example, SiN, and an upper mask layer 23 of, for example, SiO₂, are sequentially formed on the upper insulation layer 12i2 by sputtering or the like.

Then, though not shown, photolithography using a photoresist layer is conducted to form an etching mask having openings corresponding to the pattern of the second wiring grooves 12g to be finally formed, and openings 23W are formed in the upper mask layer 23 of, for example, SiO₂ through the openings in the photoresist.

Next, a photoresist 24 is once applied so as to once close the openings 23W, and photolithography is conducted to form openings 24W corresponding to the openings of the above-mentioned wiring connection holes 12h to be finally formed, in parts of the openings 23W. Through the openings 24W, etching is applied sequentially to the SiN intermediate mask layer 22 and the SiO₂ insulation layer 21, to form openings.

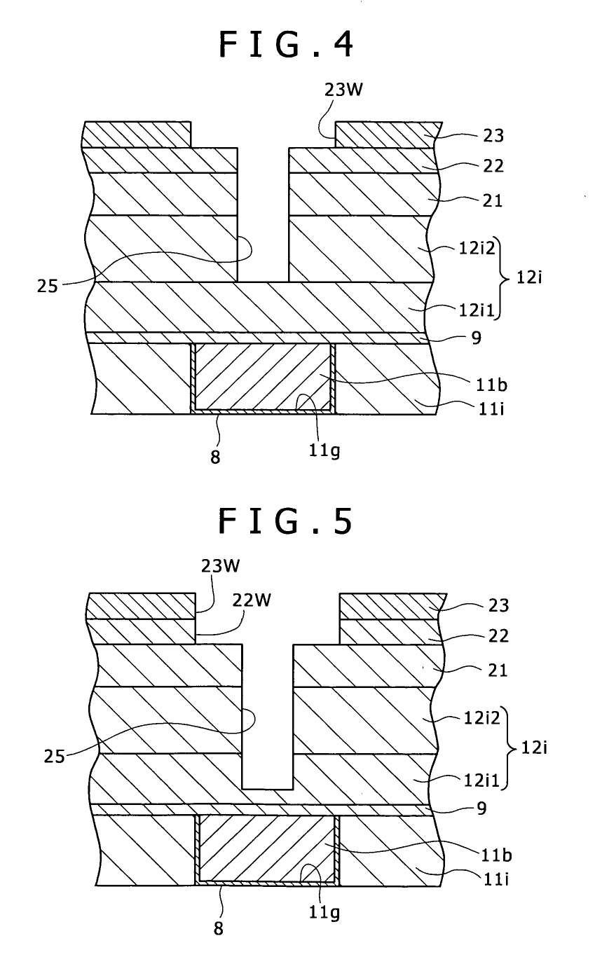

Then, as shown in FIG. 4, RIE with high selectivity is applied through the openings to etch the upper insulation layer 12i2 of the second insulation layer 12i composed, for example, of PAE, to form recessed portions 25.

As shown in FIG. 5, using the SiO₂ upper mask layer 23 as a mask and through the openings 23W thereof, etching by RIE with an etching selectivity ratio is conducted, to form openings 22W in the intermediate mask layer 22. In this instance, the lower insulation layer 12i1 is partly etched.

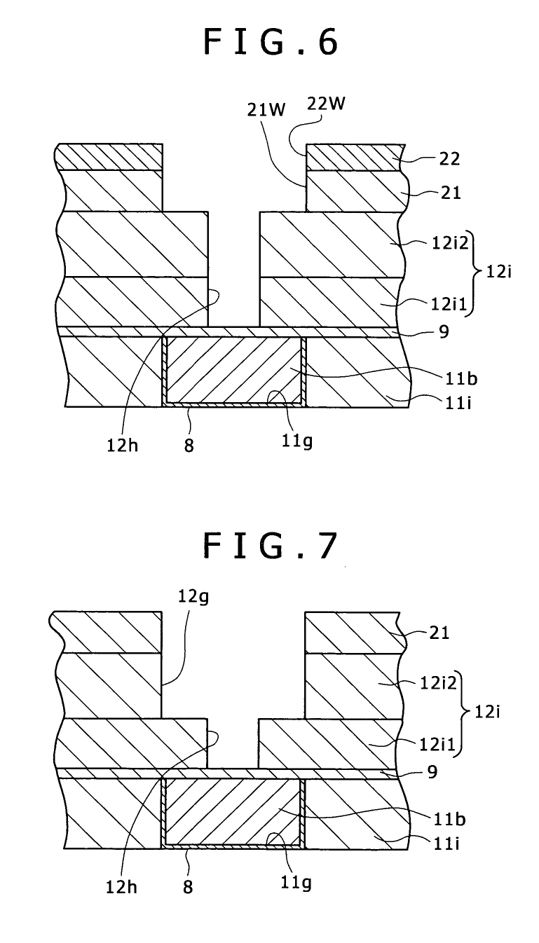

Next, as shown in FIG. 6, using the intermediate mask layer 22 as a mask and through the openings 22W thereof, etching by RIE with an etching selectivity is applied to the insulation layer 21 of, for example, SiO₂, to form openings 21W. In this instance, the SiO₂ upper mask layer 23 at the lower layer of the second insulation layer 12i is etched away.

Next, as shown in FIG. 7, the upper insulation layer 12i2 composed, for example, of PAE of the second insulation layer 12i is etched by RIE, to a depth determined by the cap layer 9 as an etching stopper.

In this manner, the second wiring grooves 12g and the wiring connection holes 12h communicated therewith are formed.

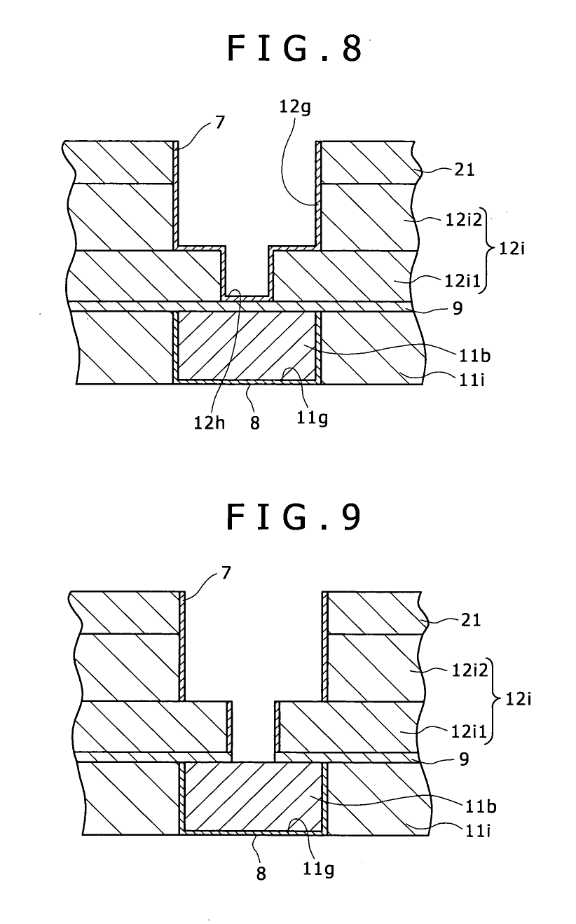

Next, as shown in FIG. 8, an insulation of SiO₂, SiN, SiC, SiCOH or the like is deposited on the inside surfaces of the wiring connection holes 12h and the second wiring grooves 12g, in a thickness of 2 to 3 nm by, for example, PE-CVD, to form the protective film 7.

The PE-CVD for forming SiO₂, for example, is conducted under a plasma environment in which reactive species such as radicals, ions, atoms, and molecules having an oxidizing action are predominant, by use of a mixture gas of silane and helium, for example.

Thereafter, as shown in FIG. 9, the protective film 7 and the cap layer 9 composed of insulation films at the bottom surfaces of the wiring connection holes 12h are removed by RIE, to expose the surface of the first buried wiring 11b. In this instance, the protective film 7 at the bottom surfaces of the second wiring grooves 12g is simultaneously removed.

Next, the etching residue upon the RIE, the surface oxide of the first buried wiring 11b, foreign matters and the like are removed by washing with an organic detergent, for example.

Thereafter, a cleaning treatment consisting of a hydrogen radical treatment or a hydrogen plasma treatment is conducted, to achieve reduction of the oxide at the Cu surface, for example, of the first buried wiring 11b at the bottom surfaces of the wiring connection holes 12h, and decomposition and removal of resist residue and the like.

The hydrogen radical treatment or hydrogen plasma treatment as the cleaning treatment may be carried out, for example, by a cleaning treatment method in which hydrogen is blown to a tungsten wire heated to 300° C., thereby generating hydrogen radicals.

At the time of the cleaning treatment, the presence of the protective film 7, or insulation film liner, promises protection of a damaged layer of the upper insulation layer 12i2 of the second insulation layer 12 formed of the low dielectric constant material, for example, PAE. This enables a DHF (buffered hydrofluoric acid) treatment after piercing of the connection holes.

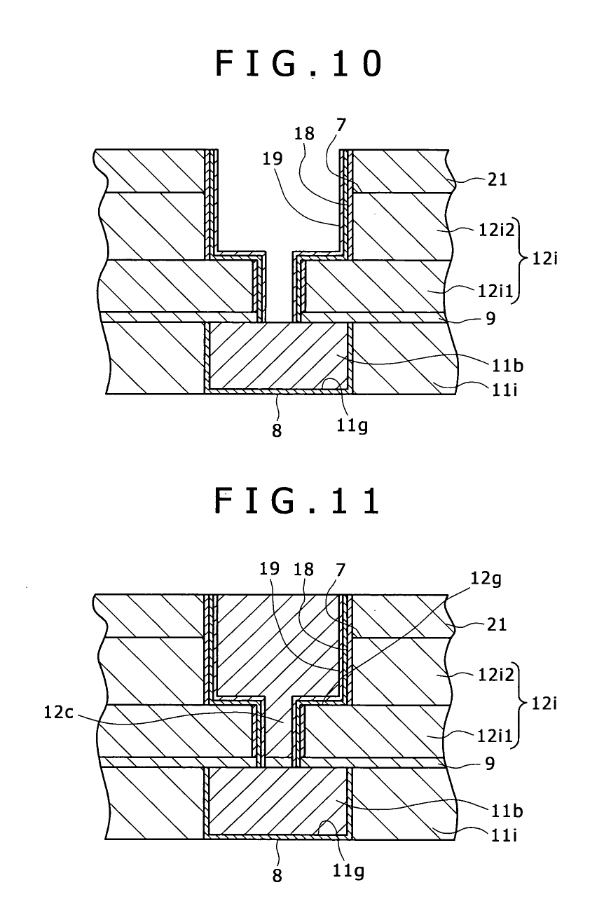

Next, as shown in FIG. 10, the barrier metal layer 18 of, for example, Ta, TaN, Ti, WN or the like is formed by sputtering or the like.

Next, for example, a Cu seed layer 19 serving as a conduction layer in electroplating and as an under layer enabling good plating is formed by sputtering or the like.

Then, for example, Cu is electroplated in a thickness of, for example, about 1 μm on the whole area of the seed layer 19, and is polished to be flat by CMP from the surface thereof, whereby as shown in FIG. 11, the wiring connection holes 12h and the second wiring grooves 12g are filled with the connection conductors 12c and, simultaneously, the second buried wiring 12b is formed, with the surface of the second buried wiring 12b and the surface of SiO₂ 21 being flattened.

In this manner, a two-layer wiring in which the first buried wiring 11b and the second buried wiring 12b are in electrical contact with each other through the connection conductors 12c is configured.

Incidentally, in the manufacturing method above, the cleaning treatment with the hydrogen radicals or hydrogen plasma may be carried out in a film forming apparatus, for example, a sputtering apparatus for forming the barrier metal 18 and the seed layer 19 in the subsequent steps, and the formation of the barrier metal layer 18 and the seed layer 19 can be performed after the cleaning treatment in the vacuum apparatus, without taking out the semiconductor substrate to the exterior.

In addition, the formation of the protective film 7 can be conducted, for example, ALD (Atomic Layer Deposition) for forming a film by single atomic layer adsorption; in this case, an extremely thin protective film 7 can be formed, whereby the CD, or variation in the width of the buried wiring 12b, can be obviated more securely.

As has been described above, after the formation of the second buried wiring 12b and the formation of the connection conductors 12c for connection between the second buried wiring 12b and the first buried wiring 11b, the process may be sequentially repeated while the thus formed wiring is regarded as a first buried wiring, whereby the multi-layer wiring structure 1 having three or more layers shown in FIG. 1 can be configured.

### Second Embodiment of the Method of Manufacturing the Multi-Layer Wiring Structure

This embodiment is the case where the protective film 7 is composed of a barrier metal layer 18. In this case, the steps shown in FIGS. 3 to 8 can be performed by adopting the same method as above-described.

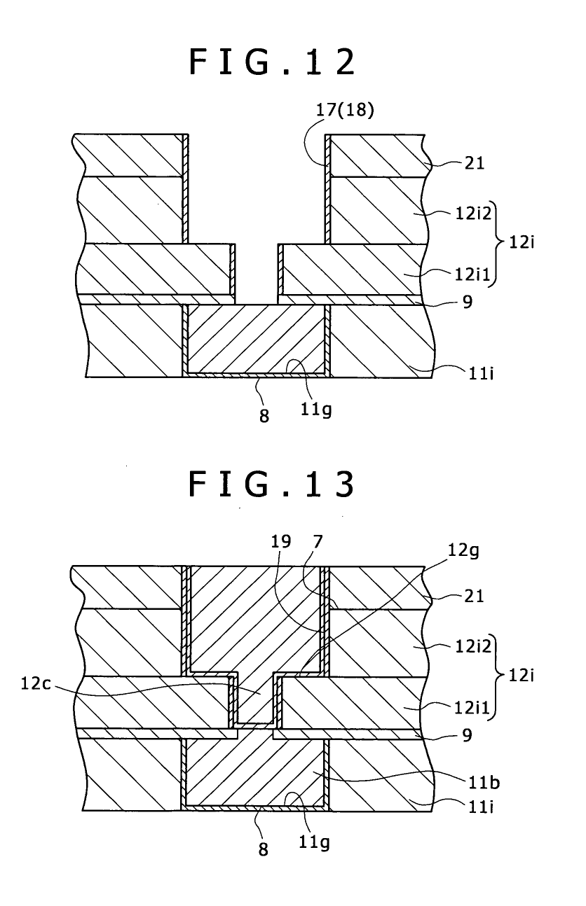

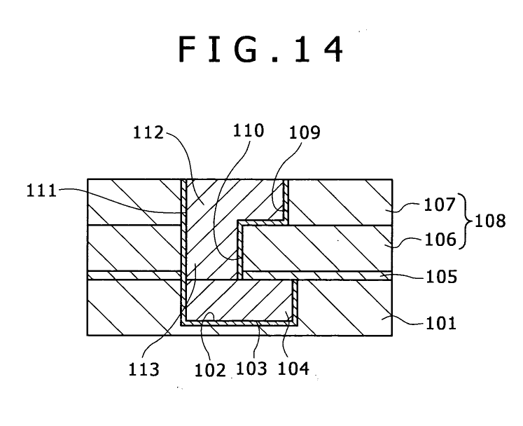

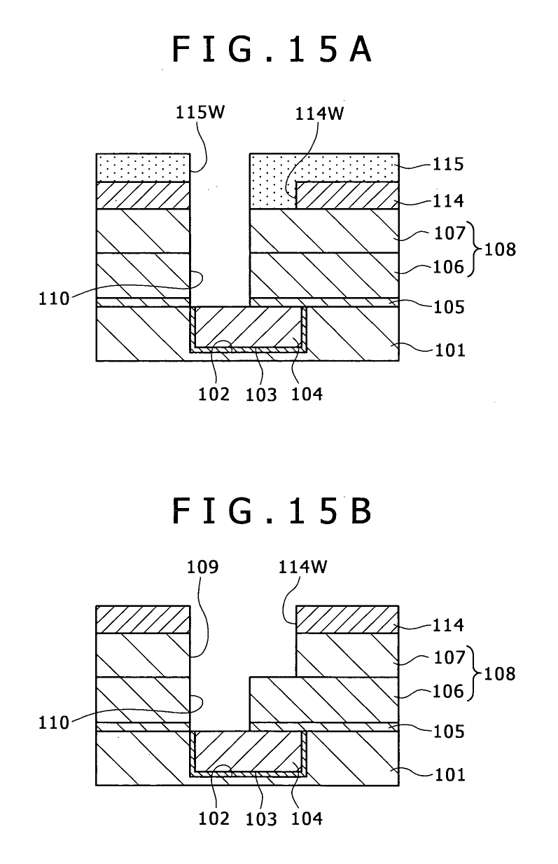

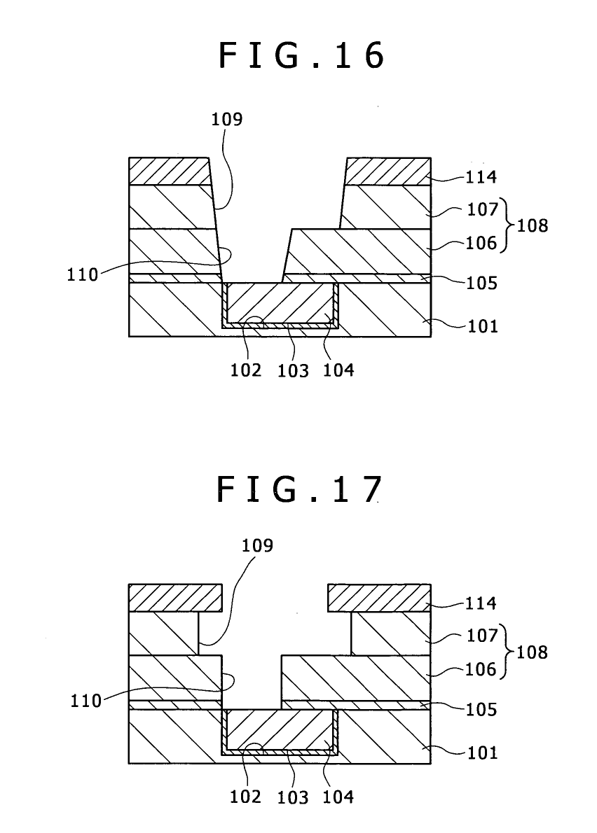

In this case, in place of the formation of the protective film 7 composed of the insulation layer, sputtering of, for example, Ta, TaN, Ti, WN or the like is conducted in a sputtering apparatus for the barrier metal, to form the barrier metal layer 18 as shown in FIG. 12.

Thereafter, introduction of argon gas and application of a voltage to the substrate 2 in a chamber of the sputtering apparatus are controlled, whereby it is possible to leave the barrier metal layer 18 on the inside surfaces of the second wiring grooves 12g and the wiring connection holes 12h, while enhancing the reverse sputtering for the surfaces intersecting the depth direction thereof so as thereby to remove the barrier metal layer 18 present there, and it is possible to expose the surface of the first buried wiring 11b at the bottom surfaces of the wiring connection holes 12h.

Thereafter, the cleaning by the hydrogen radicals or hydrogen plasma, the formation of the seed film 19, the formation of the second buried wiring 12b and the connection conductors 12c, and the like treatments are conducted in the same manner as in the above-described method.

In each of the above embodiments of the manufacturing method, the formation of the barrier metal layer 18 or the barrier metal layer 18 as the protective film 7 may be conducted as follows. The formation of a TaN film, for example, may be conducted under the following film forming conditions.
DC power: 6 kW
N₂ flow rate: 12 sccm →0 sccm (stopped during film formation)
Process gas: Ar, 8 sccm→0 sccm (temporary stopped during film formation)→12 sccm
Pressure: 0.4 Pa
Film forming temperature: 100° C.
Substrate bias: 0 W to 350 W.

The formation of a Ta film, for example, may be conducted under the following film forming conditions.
DC power: 6 kW
Process gas: Ar, 8 sccm→0 sccm (temporary stopped during film formation)→12 sccm
Pressure: 0.4 Pa
Film forming temperature: 100° C.
Substrate bias: 0 W.

According to the above-described manufacturing methods according to the present invention, it is possible to contrive an improvement in the CD, or variations in wiring width, and to manufacture a multi-layer wiring structure and a semiconductor apparatus having the multi-layer wiring structure which have stable and excellent mechanical and chemical characteristics.

While the multi-layer wiring structure of a hybrid structure has been described in the above embodiments, in the case where the second insulation layer 12i is composed of a single insulation layer, particularly, composed of a layer of alkyl-containing SiO₂ such as SiCOH as mentioned in the beginning of the description, deterioration of electrical and mechanical properties of the insulation layer due to draw-out of the alkyl groups can be obviated by forming the protective film 7 on the inside surfaces of the second wiring grooves 12g by a method similar to those in the embodiments of the manufacturing methods according to the present invention, prior to the cleaning by hydrogen radicals or hydrogen plasma.

Besides, while the first insulation layer 11i as the lowermost layer has been composed of a single layer and the single Damascene structure has been adopted in the embodiments shown in the figures, a dual Damascene structure or a hybrid structure may also be used therefor. In addition, while each of the second insulation layer 12i and the upper insulation layers has had a hybrid structure in the above embodiments, these insulation layers may be single-layer insulation layers. Thus, the components of the multi-layer wiring structure according to the present invention are not limited to the above-mentioned examples, and may have various configurations.

It should be understood by those skilled in the art that various modifications, combinations, sub-combinations and alterations may occur depending on design requirements and other factors insofar as they are within the scope of the appended claims or the equivalents thereof.

What is claimed is:

1. A multi-layer wiring structure comprising at least:
a first insulation layer having a first buried wiring formed in a first wiring groove; and
a second insulation layer formed on said first insulation layer and having a second buried wiring formed in a second wiring groove; wherein
at least said second insulation layer is provided, under said second wiring groove formed in said second insulation layer, with a wiring connection hole filled with a connection conductor for connection between said second buried wiring in said second wiring groove and said first buried wiring in said first insulation layer;
a protective film capable of enduring a cleaning treatment by a hydrogen plasma treatment or a hydrogen radical treatment carried out prior to the formation of said connection conductor in said wiring connection hole is formed to cover the inside surfaces of said second wiring groove and said wiring connection hole in said second insulation layer; and
said protective film includes a barrier metal layer for said insulation film or said connection conductor and said second buried wiring.

2. A multi-layer wiring structure comprising at least:
a first insulation layer having a first buried wiring formed in a first wiring groove; and
a second insulation layer formed on said first wiring layer and having a second buried wiring formed in a second wiring groove; wherein
at least said second insulation layer has a laminate structure of a lower insulation layer having an inorganic insulation layer and an upper insulation layer having a low dielectric constant organic insulation layer;
said upper insulation layer in said second insulation layer is provided with said second wiring groove filled with said second buried wiring, and is provided under said second wiring groove with a wiring connection hole filled with a connection conductor for connection between said second buried wiring in said second wiring groove and said first buried wiring in said lower insulation layer;
a protective film capable of enduring a cleaning treatment by a hydrogen plasma treatment or a hydrogen radical treatment carried out prior to the formation of said connection conductor in said wiring connection hole is formed to cover at least the inside surface of said second wiring groove in said upper insulation layer having said organic insulation layer; and
said protective layer has a barrier metal layer for an insulation film or said connection conductor and said second buried wiring.

3. A semiconductor apparatus having a multi-layer wiring structure on a semiconductor substrate having at least a semiconductor layer provided with a semiconductor device, wherein
said multi-layer wiring structure comprises at least a first insulation layer having a first buried wiring formed in a first wiring groove, and
a second insulation layer formed on said first insulation layer and having a second buried wiring formed in a second wiring groove;
at least said second insulation layer is provided, under said second wiring groove formed in said second insulation layer, with a wiring connection hole filled with a connection conductor for connection between said second buried wiring in said second wiring groove and said first buried wiring in said first insulation layer;
a protective film capable of enduring a cleaning treatment by a hydrogen plasma treatment or a hydrogen radical treatment carried out prior to the formation of said connection conductor in said wiring connection hole is formed to cover the inside surfaces of said second wiring groove and said wiring connection hole in said second insulation layer; and
said protective film has an insulation film or a barrier metal layer for said connection conductor and said second buried wiring.

4. A semiconductor apparatus having a multi-layer wiring structure on a semiconductor substrate having at least a semiconductor layer provided with a semiconductor device, wherein
said multi-layer wiring structure comprises at least a first insulation layer having a first buried wiring formed in a first wiring groove, and
a second insulation layer formed on said first insulation layer and having a second buried wiring formed in a second wiring groove;
at least said second insulation layer has a laminate structure of an under insulation layer having an inorganic insulation layer and an upper insulation layer having a low dielectric constant organic insulation layer;
said upper insulation layer in said second insulation layer is provided with said second wiring groove filled with said second buried wiring, and is provided under said second wiring groove with a wiring connection hole filled with a connection conductor for connection between said second buried wiring in said second wiring groove and said first buried wiring in said lower insulation layer;
a protective film capable of enduring a cleaning treatment by a hydrogen plasma treatment or a hydrogen radical treatment carried out prior to the formation of said connection conductor in said wiring connection hole is formed to cover at least the inside surface of said second wiring groove in said upper insulation layer having said organic insulation layer; and
said protective layer has an insulation film or a barrier metal layer for said connection conductor and said second buried wiring.

5. A method of manufacturing a multi-layer wiring structure, comprising the steps of:
forming a second insulation layer on a first insulation layer having a first buried wiring formed in a first wiring groove;
forming a wiring connection hole in said second insulation layer, on the upper side of a predetermined portion of said first buried wiring;
forming a second wiring groove communicated with said wiring connection hole;
forming a protective film on the inside surfaces of said wiring connection hole and said second wiring groove in said second insulation layer;
thereafter cleaning an upper surface of said first wiring at the bottom surface of said wiring connection hole by a hydrogen plasma treatment or a hydrogen radical treatment; and
thereafter forming a connection conductor connected to said first buried wiring and a second buried wiring in said wiring connection hole and in said second wiring groove, respectively; wherein
said protective film has an insulation film or a barrier metal layer for said connection conductor and said second buried wiring, said insulation film or barrier metal layer being capable of enduring the hydrogen plasma treatment or the hydrogen radical treatment.

6. A method of manufacturing a multi-layer wiring structure, comprising the steps of:
forming a second insulation layer by sequentially forming a lower insulation layer having an inorganic insulation layer and an upper insulation layer having a low dielectric constant organic insulation layer, on a first insulation layer having a first buried wiring formed in a first wiring groove;
forming a wiring connection hole in at least said lower insulation layer of said second insulation layer, on the upper side of a predetermined portion of said first buried wiring;
forming a second wiring groove communicated with said wiring connection hole limitatively in said upper insulation layer of said second insulation layer;
forming a protective film on the inside surface of said upper insulation layer fronting on said second wiring groove of said second insulation layer, at least;
thereafter cleaning an upper surface of said first wiring at the bottom surface of said wiring connection hole by a hydrogen plasma treatment or a hydrogen radical treatment; and
thereafter forming a connection conductor connected to said first buried wiring and a second buried wiring in said wiring connection hole and in said second wiring groove, respectively; wherein
said protective film has an insulation film or a barrier metal layer for said connection conductor and said second buried wiring, said insulation film or barrier metal layer being capable of enduring the hydrogen plasma treatment or the hydrogen radical treatment.

7. The method of manufacturing a multi-layer wiring structure as set forth in claim 5 or 6, wherein
said step of forming said protective film having said insulation film has the steps of forming said insulation film on the inside surfaces of said wiring connection hole and said second wiring groove, and
removing said insulation film on the bottom surface of said wiring connection hole intersecting the depth direction of said wiring connection hole and said second wiring groove by anisotropic etching including reactive ion etching to thereby expose said first buried wiring.

8. The method of manufacturing a multi-layer wiring structure as set forth in claim 5 or 6, wherein
said step of forming said protective film having said barrier metal layer has the step of applying sputtering and reverse sputtering to the inside surfaces of said wiring connection hole and said second wiring groove to remove said barrier metal layer on the bottom surface of said wiring connection hole intersecting the depth direction of said wiring connection hole and said second wiring groove, thereby exposing said first buried wiring.

9. A method of manufacturing a semiconductor apparatus having a multi-layer wiring structure on a semiconductor substrate having at least a semiconductor layer provided with a semiconductor device, wherein
said multi-layer wiring structure is manufactured by a method comprising the steps of:
forming a second insulation layer on a first insulation layer having a first buried wiring formed in a first wiring groove;
forming a wiring connection hole in said second insulation layer, on the upper side of a predetermined portion of said first buried wiring;
forming a second wiring groove communicated with said wiring connection hole;
forming a protective film on the inside surfaces of said wiring connection hole and said second wiring groove in said second insulation layer;
thereafter cleaning an upper surface of said first wiring at the bottom surface of said wiring connection hole by a hydrogen plasma treatment or a hydrogen radical treatment; and
thereafter forming a connection conductor connected to said first buried wiring and a second buried wiring in said wiring connection hole and in said second wiring groove, respectively;
said protective film having an insulation film or a barrier metal layer for said connection conductor and said second buried wiring, said insulation film or barrier metal layer being capable of enduring the hydrogen plasma treatment or the hydrogen radical treatment.

10. A method of manufacturing a semiconductor apparatus having a multi-layer wiring structure on a semiconductor substrate having at least a semiconductor layer provided with a semiconductor device, wherein
said multi-layer wiring structure is manufactured by a method comprising the steps of:
forming a second insulation layer by sequentially forming a lower insulation layer having an inorganic insulation layer and an upper insulation layer having a low dielectric constant organic insulation layer, on a first insulation layer having a first buried wiring formed in a first wiring groove;
forming a wiring connection hole in at least said lower insulation layer of said second insulation layer, on the upper side of a predetermined portion of said first buried wiring;
forming a second wiring groove communicated with said wiring connection hole limitatively in said upper insulation layer of said second insulation layer;
forming a protective film on the inside surface of said upper insulation layer fronting on said second wiring groove of said second insulation layer, at least;
thereafter cleaning an upper surface of said first wiring at the bottom surface of said wiring connection hole by a hydrogen plasma treatment or a hydrogen radical treatment; and
thereafter forming a connection conductor connected to said first buried wiring and a second buried wiring in said wiring connection hole and in said second wiring groove, respectively;
said protective film having an insulation film or a barrier metal layer for said connection conductor and said second buried wiring, said insulation film or barrier metal layer being capable of enduring the hydrogen plasma treatment or the hydrogen radical treatment.
